(19) United States
(12) Patent Application Publication
(10) Pub. No.: US 2002/0138796 A1
(43) Pub. Date: Sep. 26, 2002

(54) Intelligent performance monitoring in optical networks using FEC statistics

(76) Inventor: John M. Jacob, Bedford, MA (US)

Correspondence Address: Steven M. Mills, Esq., Mills & Onello LLP, Suite 605, 11 Beacon Street, Boston, MA, 02108, US

(21) Appl. No.: 09/815,491

(22) Filed: Mar. 23, 2001

(51) Int. Cl. G06F 11/00; G01R 31/28; H03M 13/00

(52) U.S. Cl. 714/712; 714/752

(57) ABSTRACT

An apparatus and method for monitoring performance of a communication channel or link are described. Errors in the transfer of data are detected and corrected using forward error correction (FEC). The FEC statistics are monitored to determine conditions related to performance of the system. For example, the number of errors corrected by the FEC can be monitored over predetermined periods of time. Using this approach, certain fading errors which tend to correct themselves over time without intervention can be identified, and costly, time consuming troubleshooting and repair efforts can be avoided. By monitoring the types of errors being corrected, i.e., one-bits or zero-bits, certain particular conditions, such as coherent crosstalk, can be identified. Also, monitoring the FEC statistics, particularly numbers of errors corrected, permits identification of system performance degradation at extremely low error rates, such that a Q-measurement for the system is generated.

### BACKGROUND OF THE INVENTION

High-speed digital data networks such as the Internet include a highly complex system of communication channels for transferring data. In such systems, data is transferred over multiple communication channels. In each channel, data is transferred from an input end to an output end of the channel. A transmission system at the input end formats the data and forwards it onto the channel. A reception system at the output end receives the data and processes it appropriately.

In such systems, the data is transferred over channels or links using some network transfer protocol, such as the SONET protocol or the Internet Protocol (IP). Under such a protocol, the data is transferred in packets, each of which includes a data or payload portion and a header portion. The header portion contains the information or “overhead” required to deliver the payload of the packet to its destination. It may also include additional information related to an error correction technique, such as forward error correction (FEC), used to detect and correct errors in the data. The payload portion may also include FEC bits for performing error correction. Error correction techniques such as FEC typically examine a transmitted packet to verify that all of its bits are correct. If they are not, the incorrect bits are replaced with corrected values. FEC can be used with any kind of packet or framing structure in addition to SONET and IP.

FEC can be in-band or out-of-band. In-band FEC used in SONET protocols has overhead bytes defined for FEC codes. Out-of-band FEC adds additional bytes to the protocol, e.g., SONET, by increasing the data rate. The out-of-band FEC is framed in a manner similar to SONET, that is, an overhead section and a payload section.

Because large high-speed networks are so complex, they can be prone to failures of a large variety. Isolating and correcting faults can be a very difficult and costly task, since the network can be extremely large, often stretching over thousands of miles. In many cases, troubleshooting and correcting the network can involve traveling to a distant site to replace a system component such as a transmitter, a receiver or a length of cable. To exacerbate the problem, it often occurs that a particular identified fault could be attributed to more than one failure mode. As a result, a system component may be switched out of the system without correcting the problem. In such cases, the expensive, time consuming process of replacing suspect components is typically repeated until the system resumes normal operation.

This is true, for example, in optical networks when the failure is a type of fading error, introduced by a condition such as polarization mode dispersion (PMD) or polarization dependent loss (PDL). These types of phenomena are typically due to some environmental influence such as varying temperature or ground vibrations. They introduce errors on a somewhat random basis, causing the error rate of the system to drift in one direction, and they cannot generally be corrected by replacing hardware components. In fact, correcting these faults typically does not require any system changes because they usually correct themselves after certain periods of times. Unfortunately, it often happens that these fading errors are substantial enough to cause the conventional means of repair, i.e., replacing system components, to be implemented before they correct themselves, resulting in unnecessary cost and lost time.

It would be desirable therefore to implement large high-speed networks with an intelligent performance monitoring scheme which would allow at least some of the trial-and-error of conventional approaches to be eliminated.

### SUMMARY OF THE INVENTION

Accordingly, the present invention is directed to an approach to monitoring network performance which provides more intelligence in isolating faults or fades such that unnecessary troubleshooting and repair work can be reduced or eliminated. In accordance with the invention, there is provided an apparatus and method for monitoring performance of a communication system, for example, a high-speed digital data network. The system has at least one communication channel over which data is forwarded. The data is provided with an error correction portion used to detect and correct errors in the data. The error correction portion of the data is examined to determine if an error has occurred in the data. If an error has occurred, it is corrected. The number of errors that are corrected is monitored. Using the monitored number of errors corrected, a determination is made related to a condition in the system which may be causing the errors.

The error correction approach used in accordance with the invention can be any approach which provides the error correction statistics necessary to count the number of errors corrected. By counting or monitoring the number of errors corrected, the approach of the invention is able to make a determination as to a condition in the system. For example, in one embodiment, the error correction is a forward error correction (FEC) approach. The FEC used in the invention need only provide the statistics used to make the determination, and can be one of a number of types of FEC. For example, the FEC used in accordance with the invention can use Reed Solomon FEC codes, concatenated FEC codes, Turbo FEC codes, or other types of FEC codes. In one embodiment, the FEC used is out-of-band FEC.

In one embodiment, the approach of the invention is applicable to any kind of system which transfers data in packets or frames. For example, the invention is applicable to systems which use the SONET protocol or the Internet protocol (IP) standards or any proprietary framing structure.

In one embodiment, the errors corrected by FEC are counted for a predetermined period of time, and a characteristic time is assigned to a condition associated with the errors. For example, some faults cause random trends in the number of errors corrected, and the characteristic time for such faults can be the amount of time it takes for the number of errors corrected to decrease to a level that no longer indicates a fault. When a trend in corrected errors is identified, the errors can be counted until the characteristic time expires. If after that time the error trend has not corrected itself, then conventional troubleshooting and repair techniques, e.g., switching suspect components out of the system, can be implemented. If while the characteristic time is running, the error trend returns to normal and normal system operation resumes, then no corrective action need be taken. As a result, the conventional approach of troubleshooting and repair is eliminated in a case such as this where the conventional approach would have been ineffective.

In one embodiment, the errors monitored by the intelligent performance monitoring approach of the invention are these fading errors, i.e., errors which randomly assume trends which may indicate faults and then recover without intervention. In optical systems, the fading errors can be due to various phenomena, such as polarization mode dispersion (PMD) or polarization dependent loss (PDL).

In one embodiment, the condition identified using the monitored number of errors is coherent crosstalk in the communication channel. Coherent crosstalk is an interference phenomenon between two adjacent “1” bits (marks) in optical channels. The interference between the channels can cause the 1 bit (mark) to increase or decrease in amplitude, which can result in bit errors. Coherent crosstalk typically results in bits with a value of 1 being interpreted mistakenly as 0 bits and then being corrected by FEC back to 1 bits. Hence, in the present invention, the FEC statistics, particularly the number of 0 bits corrected versus the number of 1 bits corrected, are monitored. Coherent crosstalk can be identified if the number of 1 bits corrected exceeds the number of 0 bits corrected by a predetermined threshold.

In addition to the fading errors that recover without intervention, the invention can also monitor dribble errors, i.e., errors with very small rates which increase over time due to some system degradation factor. The invention can monitor these errors to identify system degradation and predict when the system will begin failing. Corrective action can then be scheduled for a convenient time, before the system fails.

The intelligent performance monitoring of the invention can be used to provide a Q-factor measurement for the system. The Q factor provides an indication of dribble errors, i.e., errors with very small bit error rates, such that very small otherwise undetectable degradations in system performance can be detected and corrected. The Q factor measurement of the invention can be used to provide advance notification of system degradation long before the errors caused by the degradation are seen by the user and they begin to adversely affect performance.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 contains a schematic block diagram of a communication channel in which the performance monitoring of the invention can be implemented.

FIGS. 2A is a schematic plot illustrating system bit errors over time for an example system in the case in which PMD fading errors are occurring.

FIG. 2B is a schematic plot illustrating system dribble bit errors over time for an example system for the case in which normal system degradation is occurring due to some system fault.

FIG. 3 contains a schematic flow diagram which illustrates the use of FEC statistics to monitor system performance, in accordance with an embodiment of the invention.

### DETAILED DESCRIPTION OF PREFERRED EMBODIMENTS OF THE INVENTION

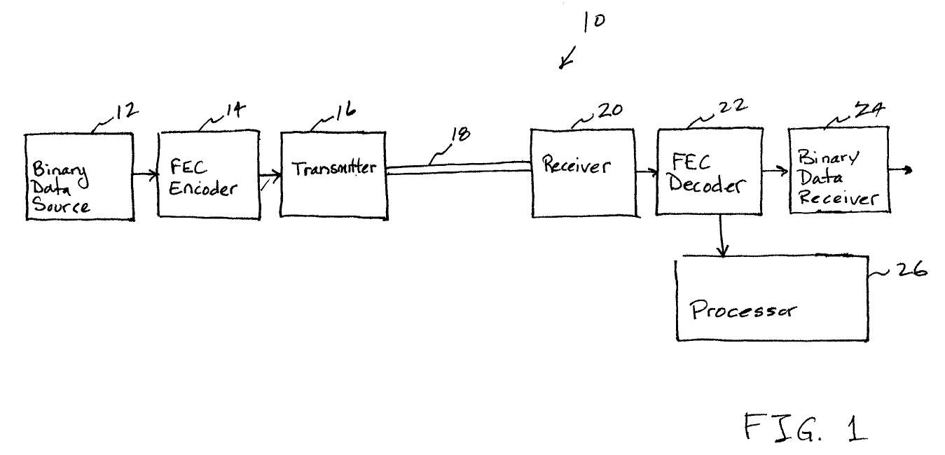

FIG. 1 contains a schematic block diagram of a communication channel or link10 in which the performance monitoring of the invention can be implemented. The communication channel or data link 10 can be part of a much larger network of links, such as in a high-speed digital network such as the Internet. The link 10 can be an optical link and can be used to transfer, for example, SONET data packets. Alternatively, the link 10 can be used to transfer data packets in accordance with the Internet Protocol. The data packets are formatted and transmitted at the transmit end of the channel 10 and are received, decoded and processed at the receive end of the link.

At the transmit end, a binary data source 12 generates the data or payload to be transmitted within a packet. The data is combined with the header or overhead portion of the packet used to ensure that the packet is transmitted to its intended destination. The overhead portion and/or the payload portion can include an error correction portion, e.g., an FEC portion, which is used to correct and detect errors in the transmitted data. The error correction, e.g., FEC, approach used in accordance with the invention is of the type which provides statistics which monitor the errors being corrected. The FEC approach can be any type of FEC which provides such statistics, such as, for example, FEC which uses Reed Solomon codes, concatenated codes, Turbo codes, or other types of FEC. The error correction portion, e.g., the FEC portion, of the data is generated and combined with the remainder of the data by an encoder 14 which in the case of FEC error correction is an FEC encoder 14. The completed data, which can be a SONET or IP packet, is transmitted by the transmitter 16 across the link 10 toward the receive end on a transmission medium 18, which can be an optical fiber.

The data is received by a receiver 20 and is analyzed by an error correction, e.g., FEC, decoder 22. The FEC portion of the header and/or payload is used to examine the data to determine if errors have occurred. If any data bits are wrong, they are changed, i.e., corrected, to their correct values. The corrected data is then forwarded to a binary data receiver or sink 24, which processes the data appropriately.

As noted above, the FEC used in accordance with the invention provides various statistics in connection with the error correction being performed. For example, the FEC statistics identify the number of errors identified and corrected. In addition, the statistics also include the values of the individual data bits corrected and the quantity of each type corrected, i.e., the number of ones and the number of zeros corrected. The FEC statistics are forwarded from the FEC decoder 22 to a processor 26, where they are processed in accordance with the invention to identify conditions and faults in the system.

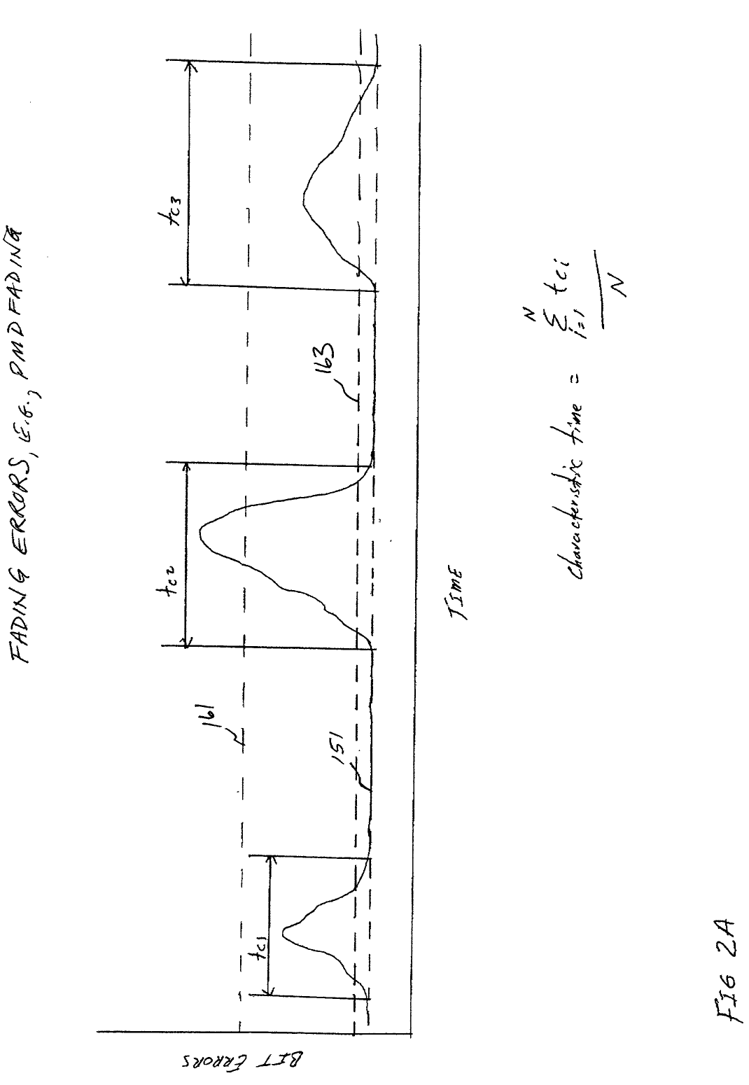

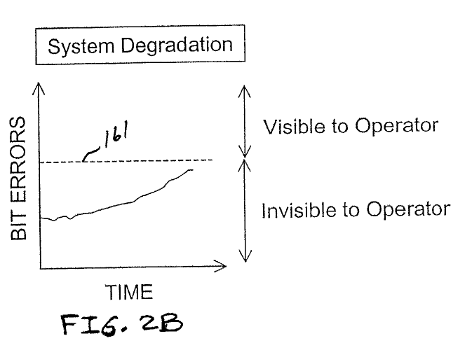

FIGS. 2A and 2B are schematic plots of system bit errors over time for an example system. FIG. 2A illustrates system performance in the presence of fading errors due to, for example, polarization mode dispersion (PMD). FIG. 2B is a schematic plot illustrating system performance under normal system degradation due to some actual system fault which may be correctable.

In both figures, all of the errors below the threshold 161 indicated by dashed lines are corrected and are therefore not visible to the operator. That is, they do not typically indicate to the operator that any system degradation is occurring. However, in accordance with the invention, these errors are seen by examining the FEC statistics.

As shown in FIG. 2A, fading errors such as PMD fading errors build up over time and then decrease by themselves without any intervention by the operator. FIG. 2A illustrates three episodes or events of increased errors due to fading. In each case, the error rates rise to a level and then decrease back to a baseline level 151, where the PMD phenomenon is no longer affecting operation of the system.

In the second illustrated episode of FIG. 2A, the error rate exceeds the threshold beyond which they cannot be corrected. At that point, the operator sees the errors in some form of system degradation or failure due to the uncorrected errors. Using a conventional approach to system debugging and repair, the uncorrected errors would indicate a system fault requiring some form of manual correction. However, in accordance with the invention, if the operator waits long enough, the error rate would return to normal without his or her intervention.

As shown in FIG. 2A, a characteristic time t_{ci} is defined for each episode. The time t_{ci} is the duration of the episode, i.e., the amount of time between when the error rate increases above the baseline error rate 151 and when it returns to the baseline 151. By analyzing a history of the errors and such episodes, a characteristic time t_{c} for the fault, i.e., PMD fading, can be calculated by the invention, such as by computing the average of the individual episode durations t_{ci}. When this time t_{c} is defined and associated with the error mode, i.e., PMD fading, then, in accordance with the invention, whenever an increase in error rate is observed such as would occur in the second episode where the errors cross the threshold 161, the operator can wait the characteristic time t_{c} for the rates to return to baseline. If the particular fault, i.e., PMD fading, associated with the characteristic time is what is causing the increase in error rate, then the rate should return to baseline by itself at about the characteristic time t_{c}. In this case, the manual repair work, which would have been performed using the conventional approach and would not have been successful in curing the problem, is eliminated.

In contrast, as shown in FIG. 2B, in the presence of some actual system fault such as a faulty subsystem, e.g., receiver or transmitter, errors continue to build up over time without recovery. Eventually, the number of errors exceeds the threshold such that all of the errors can no longer be corrected. The system performance degrades and corrective action must be taken.

Referring again to FIG. 2A, when the system compiles the error history used to identify and modify the characteristic time t_{c} for an event, it examines the error rate periodically. If an increase above baseline by a threshold indicated by dashed line 163 is detected, then a timer starts, and the errors continue to be monitored. If and when the error rate drops below the threshold 163, it is assumed to have returned to baseline 151. The timer then indicates the characteristic time t_{ci} for the event or episode i. The overall characteristic time t_{c} for the failure mode can be computed by averaging the individual t_{ci} for multiple events. The individual t_{ci} can be summed, and the sum can be divided by the number of events N. In one embodiment, an initial t_{c} can be set, and then a moving average can be used as new t_{ci} are computed to modify the overall characteristic time t_{c} for the failure mode, if desired.

A wide variety of statistical information can be generated by the data gathering approach of the invention and used to monitor performance of the system and to provide useful performance information to the user. For example, the initial t_{c} for a failure mode can be reported to the user when the system is first placed into service. This initial t_{c} can be based on system testing, observations during a break-in or integration phase, or empirical observations based on the provider's experience. The t_{c} can be modified after the system begins operating, such as by the moving average or other approach, or it can be replaced altogether by a newly computed t_{c}. In any case, as described above, the t_{c} is used to add some intelligence into the process of identifying and/or correcting failure modes, and in the case of some modes such as those due to fading errors, allow them to correct themselves without expense.

FIGS. 2A and 2B illustrate the capabilities of the performance monitoring approach of the invention. In accordance with FIG. 2A, if there is a likelihood that errors are due to PMD fading, for example, then the operator need only wait the characteristic time before performing any corrective action. If the problem is in fact due to PMD fading, then the errors will likely decrease, and no further action will need be taken. Also, FIGS. 2A and 2B both indicate that since the number of errors being corrected by FEC can be monitored, then the system can carefully monitor system performance in real time and can predict the course of system degradation. That is, the operator can predict when the number of errors will exceed the threshold and cause system performance degradation. This information can be used to schedule a corrective action for a convenient time, rather than waiting for the system to fail and then performing the correction.

In general, by monitoring and processing the statistics provided by the error correction approach being used, such as FEC, the invention provides the system user with a large amount of valuable information. The flexibility of the system in analyzing the statistics can also allow the user or system provider to tailor the information to particular needs. For example, it may be desirable to track system performance over a predefined period of time, for example, the last week or month or year. This information can readily by provided by analyzing the error correction statistics.

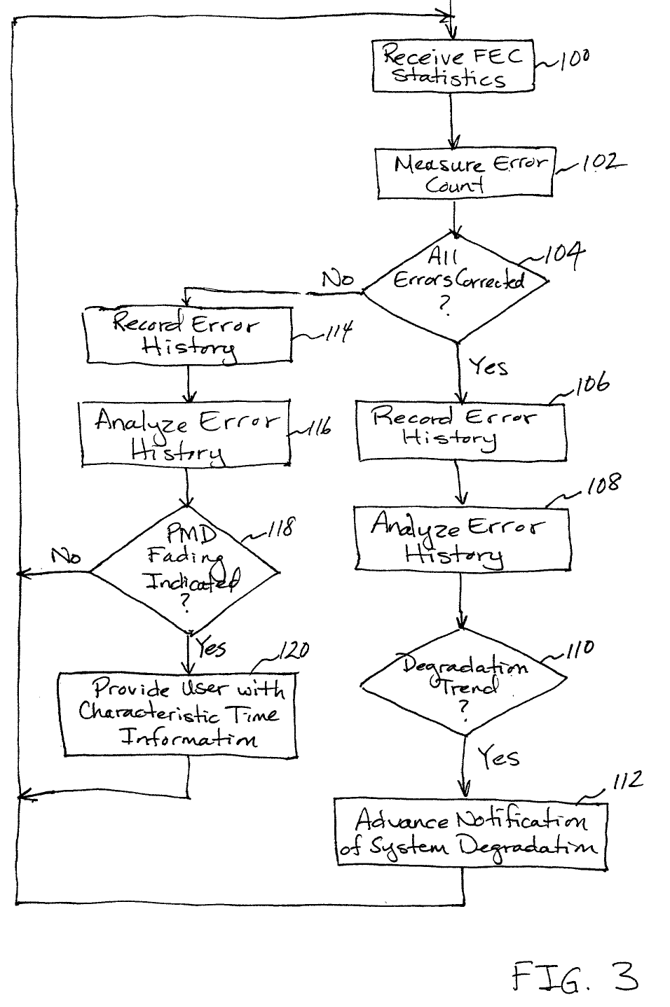

FIG. 3 contains a schematic flow diagram which illustrates the use of FEC statistics to monitor system performance in accordance with an embodiment of the invention. Periodically, such as every fifteen minutes, in steps 100 and 102, the FEC statistics are received for analysis and analyzed such as, for example, to obtain the error count over a predetermined period of time. For example, every fifteen minutes, the number of errors received over the previous minute may be determined. Next, in step 104, a determination is made as to whether all of the errors have been corrected. If so, then the error history, i.e., the error correction information for the present interval, is recorded, as illustrated by step 106, and the error history information is analyzed in step 108. The error history information is used to make determinations regarding the performance of the system over time. For example, one feature of the invention as described above is its ability to provide advance notice of system degradation even in the absence of an actual failure. To accomplish this, the invention uses the FEC statistics to generate a history of errors, even when all errors are corrected by FEC. In step 110, a determination is made as to whether the error history information indicates a degradation trend. For example, the present error reading may be compared to previous readings taken over the history of the operation of the system. If an increase in errors above baseline by a predetermined threshold for a predetermined period, without a sustained reduction in error rate is detected, then a degradation trend may be indicated. If so, advance notification of the degradation may be given to the user in step 112. After notification is given, flow returns to the top, and new input data is analyzed. If no degradation trend is indicated by the history in step 110, then flow returns directly to the beginning of the monitoring process without giving any advance notification.

Referring back to step 104, if all errors are not corrected by the FEC, then flow proceeds to steps 114 and 116, where the error history is recorded and analyzed, respectively. In step 118, a determination is made as to whether the error history indicates a known fading error behavior, such as that caused by PMD. In this case, if the error rate has exceeded the threshold 163, then the error behavior is monitored for the characteristic time to see if the error rate returns to baseline 151, as described above. If the monitoring process detects a drop in the error rate over a certain predetermined period, then it may be concluded that a fading error, i.e., an error that will return to a baseline rate, is present. If that indication is made, the user can be provided in step 120 with information related to the characteristic time for the fault, that is, the time usually taken by the system to recover from the PMD-induced fault. The user can then use this characteristic time information to define a waiting period during which no repair action will be taken, in order to allow the system to correct itself. Alternatively, the user may already have been provided with the characteristic time for various faults, e.g., PMD fading, and the system need only inform the user of the type of fault indicated by analysis of the error correction statistics. The user can then decide the steps to take, if any.

Since the invention counts errors on an individual basis, it can very accurately characterize the behavior of the system with respect to errors. It can be used to identify extremely low bit error rates (BERs) and extremely small variations in BER. Since the BER is so small, even small variations can indicate substantial degradation in system performance. For example, a change in BER from 10⁻⁵ to 10⁻¹⁴ is a tenfold degradation, to what is still an extremely low BER. Because the approach of the invention counts actual corrected errors, such small BERs can be measured. This provides a convenient means of performing a Q-factor measurement for the system. This degradation can be identified and corrected, if necessary, long before it becomes a problem.

The essence of Q measurements is to force errors to occur such that a BER can be extrapolated for the normal operating condition which is characterized by a very low undetectable BER. The Q factor measurement uses a decision circuit to intentionally force marks to be interpreted as spaces and spaces to be interpreted as marks. A decision circuit is a device in a receiver that decides if the incoming bits are to be assigned as a mark or a space by comparing the voltage, proportional to the bit amplitude, of the incoming bits to a set decision voltage. Moving the decision voltage from the optimum level forces errors to be made in the assignment of marks and spaces. This technique allows for a BER-versus-decision voltage to be realized which can be processed to determine the BER at the normal operating decision voltage. Since this technique forces errors to occur, making Q measurements on systems carrying live traffic would require additional hardware, such as dual decision circuits, to prevent corrupting the transmitted data. An advantage of using FEC is that any errors within the FEC limits can be corrected so Q techniques can intentionally force errors as long as they do not exceed the FEC correction threshold. This method does not require additional hardware. The main application of Q measurements in optical networks is for advance notification of system degradations, prior to the point at which the system would fail. This advanced notification will allow network operators to schedule repairs on systems during maintenance periods, usually during low traffic periods, as opposed to reacting to failures that could occur during peak traffic intervals.

The FEC statistics analyzed in accordance with the invention also indicate the value of the data bits corrected. That is, the number of one-bits and the number of zero-bits corrected are identified. This can be used to identify other sources of error in the system being monitored. For example, in accordance with one embodiment of the invention, coherent crosstalk can be identified if the number of one-bits corrected exceeds the number of zero-bits corrected by a predetermined threshold. Coherent crosstalk is an interference phenomenon between two adjacent “1” bits (marks) in optical channels. The interference between the channels can cause the 1 bit (mark) to increase or decrease in amplitudes, which can result in bit errors. Coherent crosstalk typically results in bits with a value of 1 being interpreted mistakenly as 0 bits and then being corrected by FEC back to 1 bits. Hence, in the present invention, the FEC statistics, particularly the number of 0 bits corrected versus the number of 1 bits corrected, are monitored. Coherent crosstalk can be identified if the number of 1 bits corrected exceeds the number of 0 bits corrected by a predetermined threshold.

While this invention has been particularly shown and described with references to preferred embodiments thereof, it will be understood by those skilled in the art that various changes in form and details may be made therein without departing from the spirit and scope of the invention as defined by the following claims.

1. A method of monitoring performance of a communication system, the communication system having at least one communication channel, the method comprising:
providing the data with an error correction portion;
examining the error correction portion of the data to determine if an error has occurred;
if an error has occurred, correcting the error;
monitoring a number of errors corrected; and
using the monitored number of errors corrected, making a determination as to a condition in the communication system.

2. The method of claim 1 wherein the error correction portion is compatible with forward error correction (FEC).

3. The method of claim 1 wherein the errors are counted for a predetermined period of time such that a characteristic time is assigned to the errors.

4. The method of claim 3 wherein the characteristic time is used to identify the condition in the system.

5. The method of claim 1 wherein the monitored number of errors is used to identify fading errors in the system.

6. The method of claim 5 wherein the fading errors include polarization mode dispersion (PMD) errors.

7. The method of claim 5 wherein the fading errors include polarization dependent loss (PDL) errors.

8. The method of claim 1 wherein the monitored number of errors is used to identify errors due to coherent crosstalk in the communication channel.

9. The method of claim 8 further comprising counting a number of bits in the data of a predetermined binary value to identify coherent crosstalk errors.

10. The method of claim 9 wherein coherent crosstalk is identified if the number of 1 bits corrected exceeds the number of 0 bits corrected by a predetermined threshold.

11. The method of claim 1 wherein the condition comprises a Q-measurement for the system.

12. The method of claim 1 wherein the communication channel forwards data in compliance with the SONET protocol.

13. The method of claim 1 wherein the communication channel forwards data in compliance with the Internet protocol (IP).

14. The method of claim 1 wherein the data is forwarded in packets.

15. The method of claim 1 wherein the data is forwarded in frames.

16. An apparatus for monitoring performance of a communication system, the communication system having at least one communication channel over which data is forwarded, the apparatus comprising:
an error correction encoding module for providing the data with an error correction portion;
an error correction decoding module for receiving the data, examining the error correction portion of the data to determine if an error has occurred, and, if an error has occurred, correcting the error; and
a processor for monitoring a number of errors corrected and, using the monitored number of errors corrected, making a determination as to a condition in the communication system.

17. The apparatus of claim 16 wherein the error correction encoding module and the error correction decoding module are forward error correction (FEC) modules.

18. The apparatus of claim 16 wherein the processor monitors the number of errors that occur within a predetermined period of time such that a characteristic time is associated with the errors.

19. The apparatus of claim 18 wherein the processor uses the characteristic time to identify the condition in the system.

20. The apparatus of claim 16 wherein the processor uses the monitored number of errors to identify fading errors in the system.

21. The apparatus of claim 20 wherein the fading errors include polarization mode dispersion (PMD) errors.

22. The apparatus of claim 20 wherein the fading errors include polarization dependent loss (PDL) errors.

23. The apparatus of claim 16 wherein the processor uses the monitored number of errors to identify errors due to coherent crosstalk in the communication channel.

24. The apparatus of claim 23 wherein the processor counts a number of corrected bits in the data of a predetermined binary value to identify coherent crosstalk errors.

25. The apparatus of claim 24 wherein the processor identifies coherent crosstalk errors if the number of 1 bits corrected exceeds the number of 0 bits corrected by a predetermined threshold.

26. The apparatus of claim 16 wherein, in making the determination as to a condition in the communication system, the processor generates a Q-measurement for the system.

27. The apparatus of claim 16 wherein the communication channel forwards data in compliance with the SONET protocol.

28. The apparatus of claim 16 wherein the communication channel forwards data in compliance with the Internet protocol (IP).

29. The apparatus of claim 16 wherein the data is forwarded in packets.

30. The apparatus of claim 16 wherein the data is forwarded in frames.

31. A method of monitoring performance of a communication system, the communication system transferring data over at least one communication channel and a forward error correction which provides statistics related to the errors corrected, the method comprising:
analyzing the statistics related to the errors corrected; and
using the analyzed statistics, making a determination as to a condition in the communication system.

32. An apparatus for monitoring performance of a communication system, the communication system transferring data over at least one communication channel and having a forward error correction which provides statistics related to the errors corrected, the apparatus comprising a processor for (i) analyzing the statistics related to the errors corrected, and, (ii) using the analyzed statistics, making a determination as to a condition in the communication system.
